(19) United States
(12) Patent Application Publication
(10) Pub. No.: US 2021/0321543 A1
(43) Pub. Date: Oct. 14, 2021

(54) LIQUID COOLED MODULE FOR NARROW PITCH SLOTS

(71) Applicant: Intel Corporation, Santa Clara, CA (US)

(72) Inventors: Guixiang TAN, Portland, OR (US); Xiang LI, Portland, OR (US); Jimmy CHUANG, Taipei (TW); Devdatta P. KULKARNI, Portland, OR (US); Casey WINKEL, Hillsboro, OR (US); Evan A. CHENELLY, Portland, OR (US)

(21) Appl. No.: 17/357,776

(22) Filed: Jun. 24, 2021

(51) Int. Cl. H05K 7/20; G06F 1/20; G11C 5/04

(52) U.S. Cl. CPC H05K 7/20809; G11C 5/04; H05K 7/20509; G06F 1/20

(57) ABSTRACT

An apparatus is described. The apparatus includes a module to be inserted into an electronic system. The module includes a first heat exchanger at one end of the module and second heat exchanger at another end of the module. The module also includes a first vapor chamber that runs along respective integrated heat spreaders of semiconductor chips disposed on a first side of the module and a second vapor chamber that runs along respective integrated heat spreaders of semiconductor chips disposed on a second side of the module. The first heat exchanger is in thermal contact with at least one of the first and second vapor chambers, and, the second heat exchanger is in thermal contact with at least one of the first and second vapor chambers.

### FIELD OF INVENTION

The field of invention generally pertains to the computing sciences, and, more specifically, to liquid cooled module for narrow pitch slots.

### BACKGROUND

With the onset of cloud computing and big data, system administrators are increasingly looking for new ways to pack as much functionality into as small a space as is practicable. However, increasingly difficult component integration challenges, particularly with respect to packaging and cooling, present themselves when trying to maximize functionality and minimize space consumption.

### FIGURES

A better understanding of the present invention can be obtained from the following detailed description in conjunction with the following drawings, in which:

FIG. 1 shows dual in-line memory modules (DIMMs) plugged into respective slots;

FIG. 2 shows DIMMs having vapor chambers on both DIMM sides plugged into respective slots;

FIG. 3 shows a DIMM having vapor chambers on both sides of the DIMM;

FIGS. 4a, 4b and 4c show different possible thermal contacts of the DIMM of FIG. 3;

FIG. 5a shows a first embodiment of the DIMM of FIG. 3;

FIG. 5b shows a second embodiment of the DIMM of FIG. 3;

FIG. 5c shows a third embodiment of the DIMM of FIG. 3;

FIG. 5d shows an air cooled DIMM;

FIG. 6 shows dimensions of a DIMM for a narrow pitch DIMM slot;

FIG. 7 shows a system;

FIG. 8 shows a data center;

FIG. 9 shows a rack.

### DETAILED DESCRIPTION

A particular challenge with respect to the increasing packaging demands concerns the packaging of modules, such as dual in-line memory modules (DIMMs), that plug into a larger system. Generally, the packing density of the modules themselves is increasing as is the number of chips and/or overall performance per module.

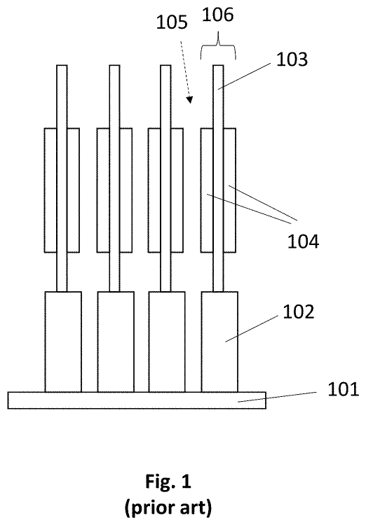

FIG. 1 shows an exemplary side view of a number of DIMMs that are plugged into, e.g., the motherboard 101 of a larger electronic system such as a computer system (for illustrative ease FIG. 1 only provides reference numbers for the rightmost DIMM). As observed in FIG. 1, the motherboard includes a socket 102 that receives a DIMM to provide both the electrical interface between the DIMM and the motherboard 101 and the mechanical coupling that firmly attaches the DIMM to the motherboard 101.

The DIMM includes a printed circuit board 103 and semiconductor chips 104 mounted on both sides of the printed circuit board 103. Unfortunately, with the continued effort to pack more functionality into smaller areas, the spacing 105 between DIMMs is becoming narrower and narrower. Moreover, the semiconductor chips themselves are generating more and more heat as their functionality is pushed further and further.

The overall situation makes it difficult if not impossible to air cool the DIMMs. That is, not enough cool air can pass through the narrowed openings between DIMMs per unit time to sufficiently cool the DIMMs' semiconductor chips. Liquid cooling can sufficiently cool the semiconductor chips. However, liquid cooling introduces “plumbing” and/or other fluidic structures to the DIMM that tend to expand the overall thickness 106 of the DIMM making the packing of DIMMs into tighter pitch slots more difficult.

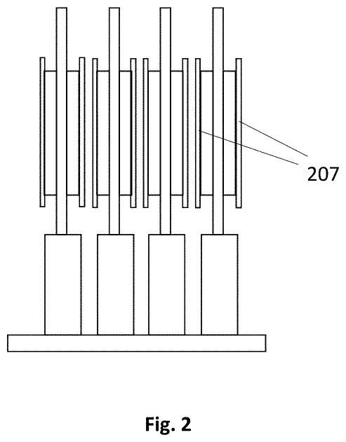

A solution, as observed in FIG. 2, is the presence of thin vapor chambers 207 that run along the surfaces of the semiconductor chips on both sides of the DIMM. A vapor chamber is a chamber having liquid that is vaporized by the heat the vapor chamber receives from the semiconductor chip(s) that the vapor chamber is in thermal contact with.

Thermal contact generally exists between two facing surfaces if they exhibit low thermal resistance between them. The surfaces can, but need not, directly contact one another. For example, two facing surfaces having a low thermal resistance material placed between them will still be in thermal contact with one another.

The vaporization of the liquid essentially draws heat from the semiconductor chips, which, in turn, cools the semiconductor chips. Importantly, owing to the nature of vaporized cooling, planar shaped (that is, large surface area and narrow thickness) vapor chambers can be formed having suitable cooling dynamics to cool a plurality of high performance semiconductor chips (such as the number of memory chips on a single side of a DIMM's printed circuit board).

Here, the cooling dynamics of a vapor chamber generally depends on the internal volume of the vapor chamber. Specifically, for the amount of heat being received by the vapor chamber, if the internal volume of the chamber can collect a sufficient amount of vapor from a large enough volume of liquid, the vaporization will effectively absorb the heat received by the chamber. In the case of the planar vapor chambers 207 of FIG. 2, the large facial surface area of the chambers 207 is sufficient to offset the narrow thickness such that effective cooling through vaporization can be achieved within the chambers 207.

Importantly, vapor chambers 207 having thicknesses of 1 mm (or less) can be realized which, as described in more detail below, provide enough headroom between neighboring DIMMs for future generation, tight pitch DIMM solutions/implementations.

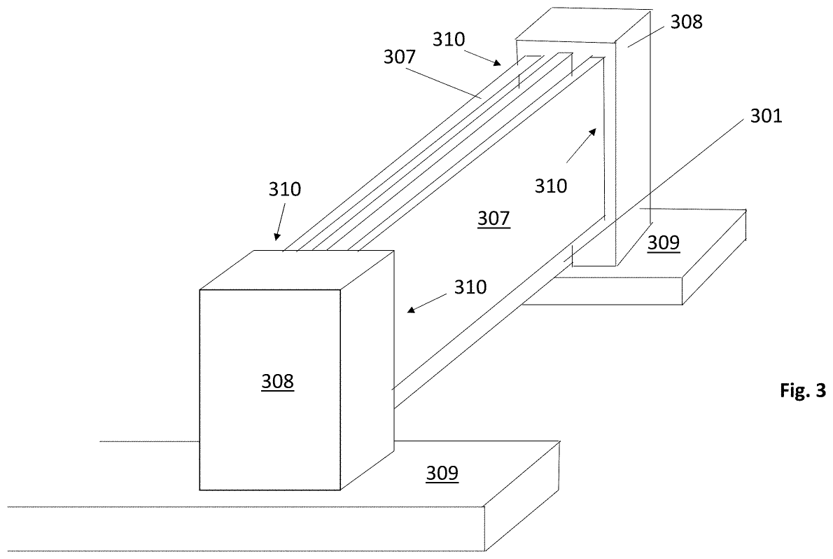

FIG. 3 shows an angled view of the improved liquid cooled DIMM of FIG. 2. For ease of drawing, only the DIMM's circuit board 301 and planar vapor chambers 307 are depicted (the semiconductor chips between the vapor chambers 307 and circuit board 301 are not shown, and, the socket that the DIMM plugs into is not shown). As depicted in FIG. 3, planar vapor chambers 307 run along both sides of the DIMM. The inner face of each vapor chamber is in thermal contact with the semiconductor chips that are directly beneath it.

The vapor chambers are arranged to be in thermal contact with heat exchangers 308 disposed at both ends of the DIMM (some embodiments may have only one heat exchanger at one DIMM end). Depending on implementation, both vapor chambers 307 can be placed in thermal contact with both heat exchangers 308, or, one of the vapor chambers can be placed in thermal contact with only one of the heat exchangers and the other vapor chamber can be placed in thermal contact with only the other heat exchanger.

Here, on a particular side of the DIMM, heat is transferred from the semiconductor chips on that side to the vapor chamber that is on that side. During operation, fluid within both vapor chambers 307 is heated to the point of vaporization. The heat from the vaporization is then transferred to the corresponding heat exchangers 308.

The heat exchangers 308, in turn, are in thermal contact with cold plates 309. The heat exchangers 308 transfer the vapor heat within the chambers 307 to the cold plates 309. In various embodiments, the cold plates 309 receive cooled fluid from the cooling apparatus of a larger electronic system. The fluid runs through the cold plates and is warmed by heat received from the exchangers 308. The cold plates 309 then returns warmed fluid back to the system's cooling apparatus.

In further embodiments, the cold plates 308 also act as part of a stable mechanical platform that one or more DIMMs are securely affixed to. For example, e.g., in order to securely mount a DIMM having the added weight of the vapor chambers 307 and the heat exchangers 308, the heat exchangers 308 are mounted to the cold plates 309 to secure the DIMM to the electrical system that the DIMM is plugged into. The DIMM also plugs into, e.g., an electrical socket connector 102 similar to the prior art approach of FIG. 1.

Depending on implementation, the vapor chambers are closed fluidic components or open fluidic components. In the case of the former (closed fluidic components), the vapor chambers are essentially sealed chambers with liquid inside. Within each chamber, the vaporization of the liquid heats the outer edges 310 of the vapor chamber that are in thermal contact with their respective heat exchangers 308.

The thermal contact between the chamber edges 310 and the heat exchangers 308 transfers heat from the vapor at the chamber edges 310 to the heat exchangers 308. The transfer of heat causes the vapor to condense back to a liquid state within its respective vapor chamber 307. Thus, under continuous operation, the liquid within the chambers 307 is continually being vaporized while the vapor at the chamber edges 310 is continually being condensed back into liquid.

In the case of the later (open fluidic components), vapor flows into the heat exchangers 308. That is, a fluidic channel of some kind exists between each of the vapor chambers 307 and at least one of the heat exchangers 308. The heat exchangers 308 transfer heat from their received vapor to the cold plates 309, which, in turn, causes condensation of the vapor back into a fluid. The condensed fluid within the heat exchangers 308 is then returned to the vapor chambers 307 and the process repeats.

In the closed fluidic approach there is little/no concern regarding internal fluidic pressures (the liquid simply remains within the vapor chambers). By contrast, in the open fluid approach, the pressure of the liquid within the heat exchangers 308 should be more than the pressure of the liquid within the vapor chambers 307 to ensure the return of fluid from the heat exchangers 308 back into the vapor chambers 307. According to one approach, as explained in more detail below, gravity is used to provide the requisite pressure differential.

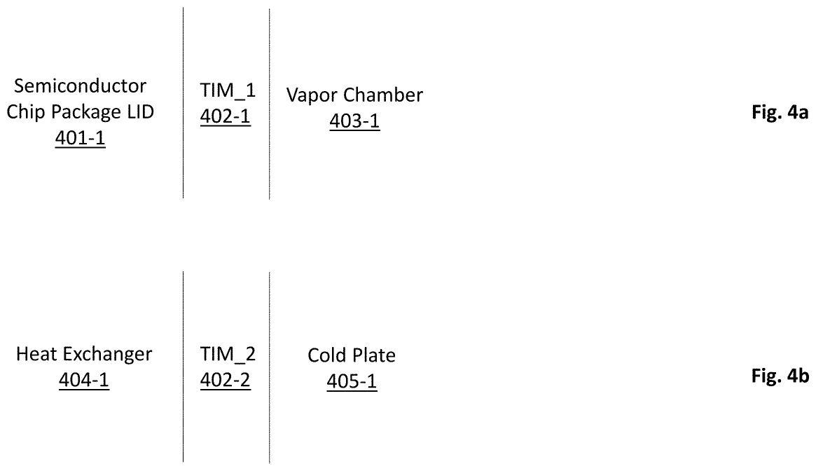

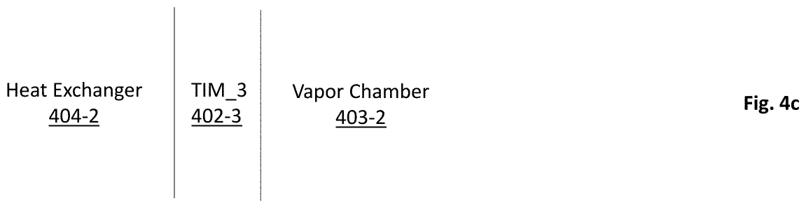

FIGS. 4a, 4b and 4c show more detailed views of the possible thermal contact structures that can exist in the approach of FIG. 3. As observed in FIG. 4a, a first thermal interface material (TIM) 402-1 can be located between the outer surfaces of a semiconductor chip package lid (integrated heat spreaders (IHS)) and the inner/under sides of a vapor chamber 403-1 (a single chamber can entertain the structure of FIG. 4a, e.g., for each of multiple semiconductor chips on the same side of the DIMM as the vapor chamber).

As observed in FIG. 4b, a second TIM 402-2 can be located between a heat exchanger 404-1 and a cold plate 405-1. As observed in FIG. 4c, a third TIM 402-3 can be located between a vapor chamber 403-2 (or outer edge or region thereof) and a heat exchanger 404-2. The approach of FIG. 4c can be particularly useful if the vapor chambers are closed. Each TIM 402-1,2,3 improves the thermal transfer efficiency between the two components it is placed between. Depending on the implementation variations, the contact surface could be brazed to reduce contact resistance (assuming serviceability is not adversely impacted). For example, heat exchanger 404-1 could be brazed on cold plate 405-1, e.g., assuming the heat exchanger does not need to be disassembled from the cold plate for serviceability.

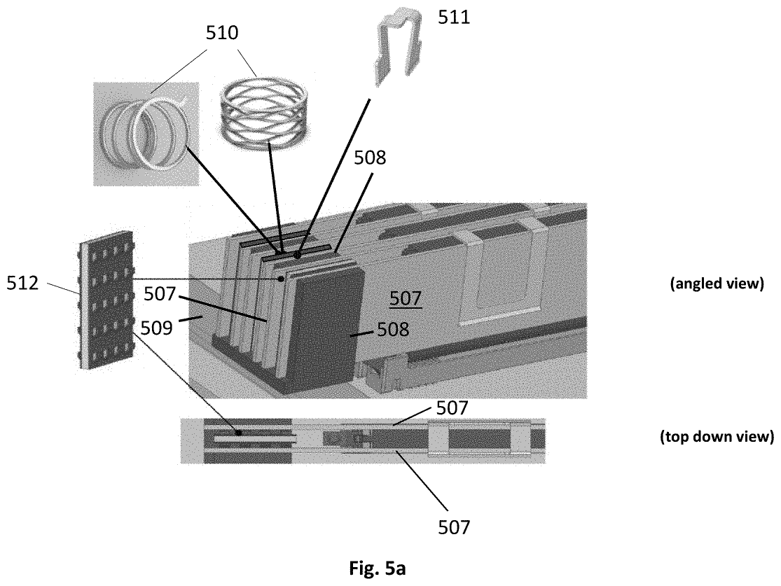

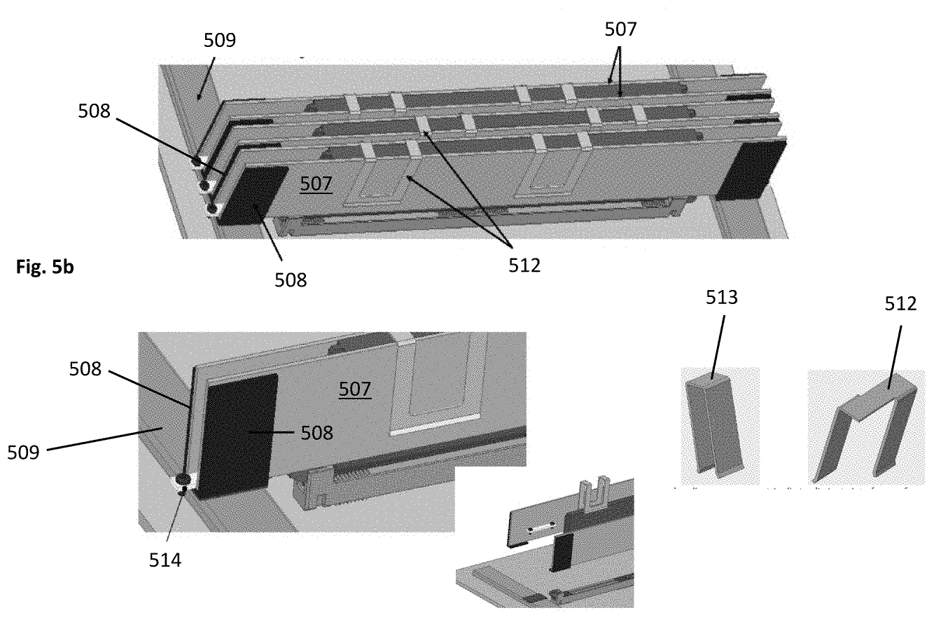

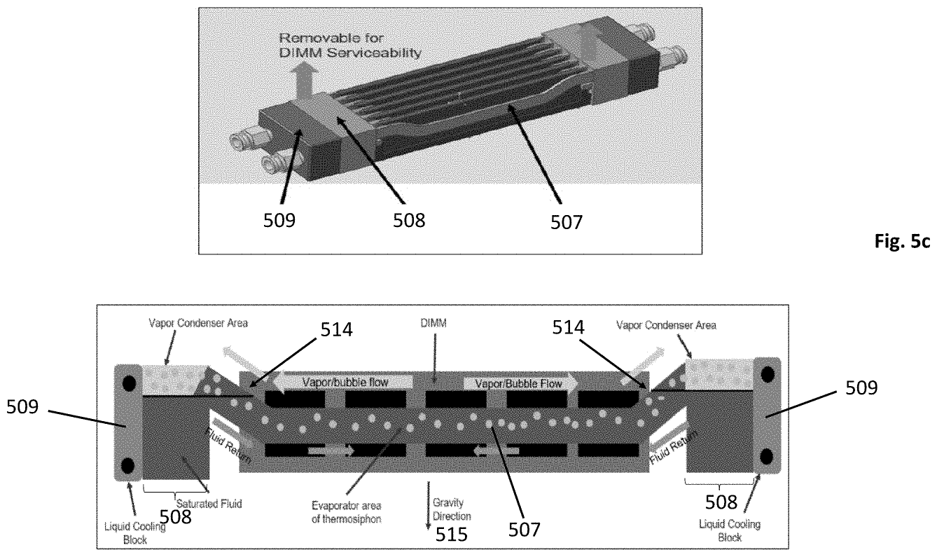

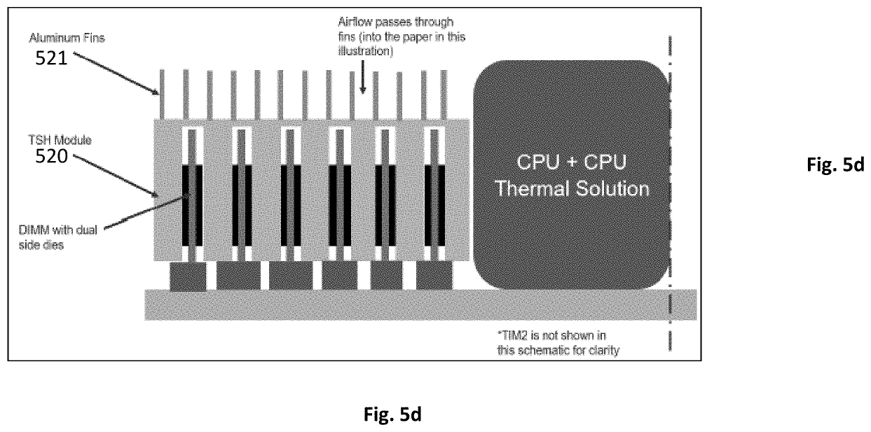

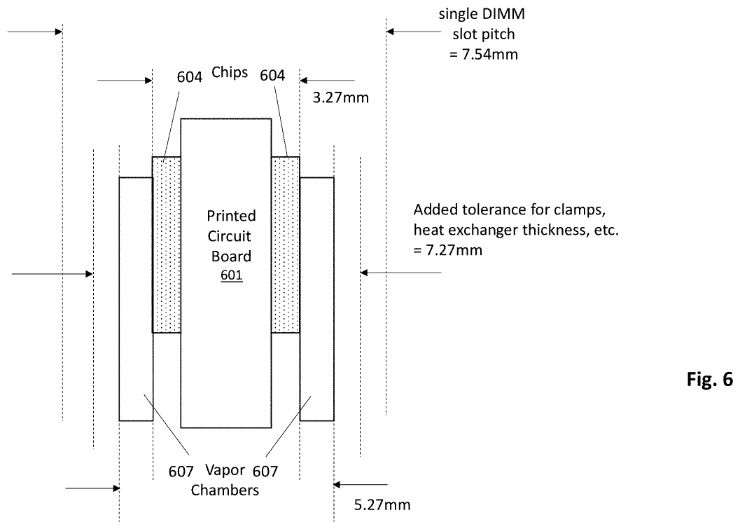

FIGS. 5a, 5b and 5c show different DIMM embodiments that conform to the general approach of FIGS. 2 and 3.

FIG. 5a shows a first approach where heat is drawn from the vapor chambers 507 to the heat exchanger surfaces 508. The heat is then transferred from the heat exchanger 508 to the cold plate 509.

Here, a compressible part 512 is inserted between the vapor chambers 507 at the DIMM edge (for ease of drawing FIG. 5a only shows one of the DIMM edges for each of three neighboring DIMMs). The compressible part 512, when compressed between both vapor chambers 507, applies pressure on the thermal contact structure of FIG. 4c (which exists on both DIMM faces) to reduce the thermal contact resistance between the vapor chambers 507 and the heat exchanger 508. The compressible part could be implemented in various ways, including but not limited to a insert 512, one or more coil springs 510 or a leaf spring 511. In various embodiments the compressible part 510/511/512 can be easily disassembled for service.

In the case of a spring 510/511, when a spring is compressed the spring exerts a force that resists the compressing action. Here, with one end of the spring 510/511 being coupled or otherwise attached to one of the vapor chambers 507 and the other end of the spring being coupled or otherwise attached to the other of the vapor chambers 507, the spring is compressed between the vapor chambers which presses the vapor chambers 507 against the heat exchanger 508.

In extended embodiments, the heat exchanger 508 is integrated into the cold plate 509 as a single piece part, or, the heat exchanger 508 is replaced with cold plate “fins” that rise up from the base of the cold plate 509 and make direct contact to the vapor chamber surfaces (similar to the heat exchanger 508 as observed in FIG. 5a). In embodiments that include cold plate fins, a single fin can exist between each pair of neighboring DIMMs (which would cause a single fin to receive, on opposite fin faces, heat from the outer faces of the vapor chambers of different DIMMs).

FIG. 5b shows another approach in which the heat exchanger 508 is brazed on to each of the vapor chambers 507 to remove TIM-3 from the thermal contact structure of FIG. 4c. As such, the heat exchanger 508 is integrated with the vapor chambers 507 rather than the cold plate base 509. As with the embodiment of FIG. 5a, heat is drawn from the heat exchanger 508 by the cold plate 509 along the heat exchanger's bottom surface. Additionally, the heat exchanger 508 can be mechanically secured to the cold plate 509 with a retention nut or screw 514, which, in turn, helps enhance the thermal transfer efficiency between the heat exchanger 508 and the cold plate 509. Multiple heat exchangers can be mounted to the same cold plate 509 to receive multiple DIMMs. The embodiment of FIG. 5b is also easily disassembled for DIMM servicing.

Although the embodiments of FIGS. 5a and 5b above have been directed to closed vapor chambers, it is conceivable that open vapor chambers can be used if fluidic conduits exist that connect heat exchanger and vapor chamber surfaces that face one another. Alternatively, a flat heat pipe or other high thermally conductive material can be used in place of the vapor chambers 507 (e.g., to act as a heat sink). The embodiments of FIGS. 5a and 5b also depict the use of clips 512 that keep the vapor chambers 507 on both sides of the DIMM pressed against their respective semiconductor chip lids along the run length of the DIMM. The clips can have non-aligned legs 512 or aligned legs 513.

It is also possible that sufficient cooling is effected with a heat exchanger and cold plate that resides on only one end of the DIMM. For that case, the vapor chamber could be shortened to cover, e.g., only the DIMM's DRAM chips.

FIG. 5c shows another embodiment in which the vapor chamber 507 is open rather than closed. The particular embodiment of FIG. 5c shows a single sided DIMM having chips and a vapor chamber 507 on only one side of the DIMM. In alternate embodiments, the DIMM can have chips and vapor chambers on both sides of the DIMM.

As observed in FIG. 5c, the vapor chamber 507 is angled 514 so that vapor that is created along the run length of the DIMM “rises up” into an upper portion of the heat exchanger 508. The rising of the vapor is dependent on the orientation of the DIMM relative to gravity. That is, if the gravitational force is as depicted 515, the lighter vapor will rise above the denser liquid. As such, condensation of the vapor occurs within an upper region of the heat exchanger.

Additionally, the level of the vapor chamber in between the angled portions is beneath the level of the liquid within the heat exchanger 508. Because of the direction of the gravitational force 515, if an opening in the heat exchanger that connects to the vapor chamber 507 is above the level of the vapor chamber 507, the liquid will “waterfall down the angled part 514 of the vapor chamber from heat exchanger 508 into the vapor chamber. The specific embodiment of FIG. 5c also shows the same opening being used between the vapor chamber 507 and the heat exchanger 508 to transfer vapor from the vapor chamber 507 into the heat exchanger 508, and, transfer liquid from the heat exchanger 508 to the vapor chamber 507. In other embodiments two different openings/channels can exist between the vapor chamber 507 and heat exchanger (one for vapor flow, one for fluid flow).

As observed in FIG. 5c, the heat exchanger 508 is in thermal contact with a cold plate 509. The cold plate 509 draws heat from the vapor in the heat exchanger 508 which causes the condensation of the vapor within the heat exchanger 508. As depicted, the cold plate 509 has dedicated fluid input and output ports per DIMM. In other embodiments the cold plate 509 can, e.g., be a longer element that the heat exchangers of multiple DIMMs are in thermal contact with.

The specific embodiment of FIG. 5c uses gravity to drive condensed fluid from the heat exchanger 508 into the vapor chamber 507. Other embodiments may include a wick-like structure in the conduits between the vapor chambers and heat exchangers to draw condensed fluid from the heat exchangers into the vapor chambers through capillary action. Such embodiments may partially depend on gravity, or, not depend on gravity at all.

In various implementations of the approach of FIG. 5c (or even the approaches of FIGS. 5a and/or 5b), the vapor chamber is not composed of a rigid material which, in turn, allows the vapor chamber to collapse and expand depending on the heat it is receiving from the chips on the DIMM. Specifically, when the chips are not dissipating much (or any) heat, the vapor chamber collapses into a retracted shape because there is little/no vapor pressure in the chamber. By contrast, when the chips are dissipating substantial heat, the induced vapor pressure causes the vapor chamber to expand (balloon outward).

This feature could be useful for easy insertion and removal of a DIMM. Specifically, if the DIMM is being inserted into a socket array with narrow pitch, the DIMM is not receiving any electrical power and the DIMM's semiconductor chips are not operating. As such, the DIMM's vapor chambers are collapsed which allows for easy insertion of the DIMM into its socket. When the DIMM begins to receive electrical power and its chips begin operating, the DIMM transfers heat to the vapor chamber which causes the vapor chamber to expand.

Depending on implementation, the shape and amount of material used for the vapor chamber either permits or does not permit the vapor chamber to “press” against a neighboring, expanded vapor chamber of a DIMM in a neighboring slot. If the later (neighboring vapor chambers can press against one another when expanded), if the vapor chambers are composed of electrically conductive material (e.g., aluminum foil) they should be grounded or otherwise at same potential.

In the case of DIMM removal, power is removed from the DIMM or its chips cease operating before the removal. As such, the vapor chamber will collapse resulting in easy removal of the DIMM from the narrow pitch socket array.

FIG. 5d shows an air-cooled solution in which the respective sides of multiple DIMMs plugged into a socket array are each in thermal contact with a block mass 520 rather than a vapor chamber. The block mass includes fins 521. Heat from the DIMM's semiconductor chips are transferred to the block mass 520. Cooled air is directed to flow in between the fins 521 which transports heat away from the fins and the block mass 520 thereby regulating the temperatures of the DIMMs' respective semiconductor chips.

In order to realize any/all of the above described solutions in narrow DIMM socket implementations, in various embodiments, each of the thin vapor chambers 507 has a total thickness of 1 mm or less. FIG. 6 illustrates an embodiment of the respective thicknesses of the various components of a complete DIMM for a DIMM socket implementation having a pitch of 7.54 mm. Here, in order to easily swap DIMMs in and out of their respective sockets, the total thickness of the DIMM, including its vapor chambers and any additional components, should be appreciably less than 7.54 mm (e.g., 7.35 mm or less).

As observed in FIG. 6, the thickness of the DIMM printed circuit board 601 and the combined height of the packaged semiconductor chips 604 on both sides of the DIMM amounts to 3.27 mm. A 1 mm thick vapor chamber 607 on each side of the DIMM adds another 2 mm to the combined thickness (=5.27 mm). Finally, allowing another 1 mm per side for thickness of any additional DIMM components (e.g., clamps, heat exchanger(s) thickness, etc.) adds another 2 mm for a total DIMM thickness of 7.27 mm. With this particular thickness, multiple DIMMs can be plugged into a bank of 3.27 mm pitch slots where each DIMM has chips and a vapor chamber on both sides of the DIMM, and, the DIMM can be easily plugged into and removed from a slot even if the neighboring slots are populated with the same type of DIMM.

As discussed above, various DIMM embodiments include memory chips on both sides of the DIMM or one side of the DIMM. The memory chips can be of various forms include dynamic random access memory (DRAM), flash memory, three-dimensional non volatile random access memory (e.g., phase change random access memory, dielectric random access memory, magnetic random access memory, spin transfer torque random access memory, etc.).

Although the discussion above has been directed to memory modules, other types of modules can employ the teachings provided herein. Here, such modules can include high performance logic chips other than memory chips such as, to name a few, processor semiconductor chips (e.g., graphics or general purpose), accelerator semiconductor chips, custom application specific integrated circuits (ASICs), peripheral controllers, etc.

Although embodiments described above have stressed DIMM form factor memory modules, other double-sided modules, such as any module that is to fit in a narrow pitch slot, but having a form factor other than an industry standard DIMM form factor (e.g., “ruler” modules) can make use of the teachings provided herein.

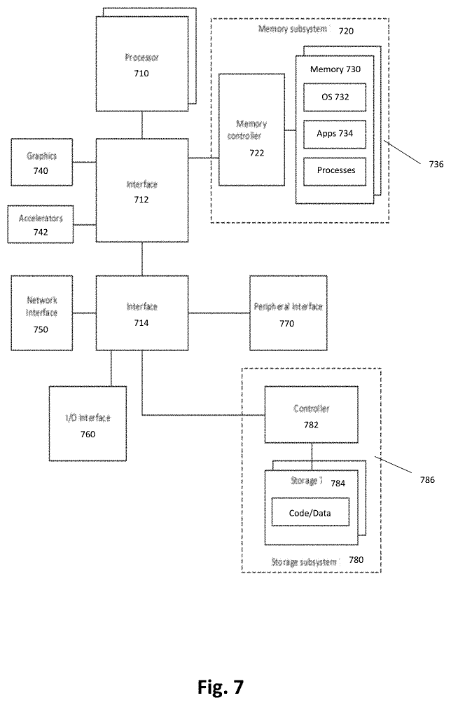

FIG. 7 depicts an example system. The system can use the teachings provided herein. System 700 includes processor 710, which provides processing, operation management, and execution of instructions for system 700. Processor 710 can include any type of microprocessor, central processing unit (CPU), graphics processing unit (GPU), processing core, or other processing hardware to provide processing for system 700, or a combination of processors. Processor 710 controls the overall operation of system 700, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 700 includes interface 712 coupled to processor 710, which can represent a higher speed interface or a high throughput interface for system components that needs higher bandwidth connections, such as memory subsystem 720 or graphics interface components 740, or accelerators 742. Interface 712 represents an interface circuit, which can be a standalone component or integrated onto a processor die. Where present, graphics interface 740 interfaces to graphics components for providing a visual display to a user of system 700. In one example, graphics interface 740 can drive a high definition (HD) display that provides an output to a user. High definition can refer to a display having a pixel density of approximately 100 PPI (pixels per inch) or greater and can include formats such as full HD (e.g., 1080p), retina displays, 4K (ultra-high definition or UHD), or others. In one example, the display can include a touchscreen display. In one example, graphics interface 740 generates a display based on data stored in memory 730 or based on operations executed by processor 710 or both. In one example, graphics interface 740 generates a display based on data stored in memory 730 or based on operations executed by processor 710 or both.

Accelerators 742 can be a fixed function offload engine that can be accessed or used by a processor 710. For example, an accelerator among accelerators 742 can provide compression (DC) capability, cryptography services such as public key encryption (PKE), cipher, hash/authentication capabilities, decryption, or other capabilities or services. In some embodiments, in addition or alternatively, an accelerator among accelerators 742 provides field select controller capabilities as described herein. In some cases, accelerators 742 can be integrated into a CPU socket (e.g., a connector to a motherboard or circuit board that includes a CPU and provides an electrical interface with the CPU). For example, accelerators 742 can include a single or multi-core processor, graphics processing unit, logical execution unit single or multi-level cache, functional units usable to independently execute programs or threads, application specific integrated circuits (ASICs), neural network processors (NNPs), “X” processing units (XPUs), programmable control logic, and programmable processing elements such as field programmable gate arrays (FPGAs). Accelerators 742 can provide multiple neural networks, processor cores, or graphics processing units can be made available for use by artificial intelligence (Al) or machine learning (ML) models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other Al or ML model. Multiple neural networks, processor cores, or graphics processing units can be made available for use by Al or ML models.

Memory subsystem 720 represents the main memory of system 700 and provides storage for code to be executed by processor 710, or data values to be used in executing a routine. Memory subsystem 720 can include one or more memory devices 730 such as read-only memory (ROM), flash memory, volatile memory, or a combination of such devices. Memory 730 stores and hosts, among other things, operating system (OS) 732 to provide a software platform for execution of instructions in system 700. Additionally, applications 734 can execute on the software platform of OS 732 from memory 730. Applications 734 represent programs that have their own operational logic to perform execution of one or more functions. Processes 736 represent agents or routines that provide auxiliary functions to OS 732 or one or more applications 734 or a combination. OS 732, applications 734, and processes 736 provide software logic to provide functions for system 700. In one example, memory subsystem 720 includes memory controller 722, which is a memory controller to generate and issue commands to memory 730. It will be understood that memory controller 722 could be a physical part of processor 710 or a physical part of interface 712. For example, memory controller 722 can be an integrated memory controller, integrated onto a circuit with processor 710. In some examples, a system on chip (SOC or SoC) combines into one SoC package one or more of: processors, graphics, memory, memory controller, and Input/Output (I/O) control logic.

A volatile memory is memory whose state (and therefore the data stored in it) is indeterminate if power is interrupted to the device. Dynamic volatile memory requires refreshing the data stored in the device to maintain state. One example of dynamic volatile memory incudes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory, JESD325, originally published by JEDEC in October 2013, LPDDR5 (currently in discussion by JEDEC), HBM2 (HBM version 2), currently in discussion by JEDEC, or others or combinations of memory technologies, and technologies based on derivatives or extensions of such specifications. The JEDEC standards are available at www.jedec.org.

In various implementations, memory resources can be “pooled”. For example, the memory resources of memory modules installed on multiple cards, blades, systems, etc. (e.g., that are inserted into one or more racks) are made available as additional main memory capacity to CPUs and/or servers that need and/or request it. In such implementations, the primary purpose of the cards/blades/systems is to provide such additional main memory capacity. The cards/blades/systems are reachable to the CPUs/servers that use the memory resources through some kind of network infrastructure such as CXL, CAPI, etc.

While not specifically illustrated, it will be understood that system 700 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect express (PCIe) bus, a HyperTransport or industry standard architecture (ISA) bus, a small computer system interface (SCSI) bus, Remote Direct Memory Access (RDMA), Internet Small Computer Systems Interface (iSCSI), NVM express (NVMe), Coherent Accelerator Interface (CXL), Coherent Accelerator Processor Interface (CAPI), Cache Coherent Interconnect for Accelerators (CCIX), Open Coherent Accelerator Processor (Open CAPI) or other specification developed by the Gen-z consortium, a universal serial bus (USB), or an Institute of Electrical and Electronics Engineers (IEEE) standard 1394 bus.

In one example, system 700 includes interface 714, which can be coupled to interface 712. In one example, interface 714 represents an interface circuit, which can include standalone components and integrated circuitry. In one example, multiple user interface components or peripheral components, or both, couple to interface 714. Network interface 750 provides system 700 the ability to communicate with remote devices (e.g., servers or other computing devices) over one or more networks. Network interface 750 can include an Ethernet adapter, wireless interconnection components, cellular network interconnection components, USB (universal serial bus), or other wired or wireless standards-based or proprietary interfaces. Network interface 750 can transmit data to a remote device, which can include sending data stored in memory. Network interface 750 can receive data from a remote device, which can include storing received data into memory. Various embodiments can be used in connection with network interface 750, processor 710, and memory subsystem 720.

In one example, system 700 includes one or more input/output (I/O) interface(s) 760. I/O interface 760 can include one or more interface components through which a user interacts with system 700 (e.g., audio, alphanumeric, tactile/touch, or other interfacing). Peripheral interface 770 can include any hardware interface not specifically mentioned above. Peripherals refer generally to devices that connect dependently to system 700. A dependent connection is one where system 700 provides the software platform or hardware platform or both on which operation executes, and with which a user interacts.

In one example, system 700 includes storage subsystem 780 to store data in a nonvolatile manner. In one example, in certain system implementations, at least certain components of storage 780 can overlap with components of memory subsystem 720. Storage subsystem 780 includes storage device(s) 784, which can be or include any conventional medium for storing large amounts of data in a nonvolatile manner, such as one or more magnetic, solid state, or optical based disks, or a combination. Storage 784 holds code or instructions and data 786 in a persistent state (e.g., the value is retained despite interruption of power to system 700). Storage 784 can be generically considered to be a “memory,” although memory 730 is typically the executing or operating memory to provide instructions to processor 710. Whereas storage 784 is nonvolatile, memory 730 can include volatile memory (e.g., the value or state of the data is indeterminate if power is interrupted to system 700). In one example, storage subsystem 780 includes controller 782 to interface with storage 784. In one example controller 782 is a physical part of interface 714 or processor 710 or can include circuits or logic in both processor 710 and interface 714.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of system 700. More specifically, power source typically interfaces to one or multiple power supplies in system 700 to provide power to the components of system 700. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, system 700 can be implemented as a disaggregated computing system. For example, the system 700 can be implemented with interconnected compute sleds of processors, memories, storages, network interfaces, and other components. High speed interconnects can be used such as PCIe, Ethernet, or optical interconnects (or a combination thereof). For example, the sleds can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

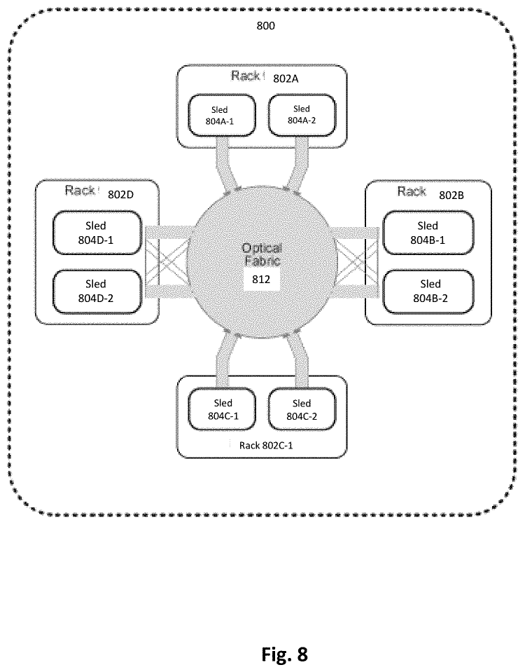

FIG. 8 depicts an example of a data center. Various embodiments can be used in or with the data center of FIG. 8. As shown in FIG. 8, data center 800 may include an optical fabric 812. Optical fabric 812 may generally include a combination of optical signaling media (such as optical cabling) and optical switching infrastructure via which any particular sled in data center 800 can send signals to (and receive signals from) the other sleds in data center 800. However, optical, wireless, and/or electrical signals can be transmitted using fabric 812. The signaling connectivity that optical fabric 812 provides to any given sled may include connectivity both to other sleds in a same rack and sleds in other racks. Data center 800 includes four racks 802A to 802D and racks 802A to 802D house respective pairs of sleds 804A-1 and 804A-2, 804B-1 and 804B-2, 804C-1 and 804C-2, and 804D-1 and 804D-2. Thus, in this example, data center 800 includes a total of eight sleds. Optical fabric 812 can provide sled signaling connectivity with one or more of the seven other sleds. For example, via optical fabric 812, sled 804A-1 in rack 802A may possess signaling connectivity with sled 804A-2 in rack 802A, as well as the six other sleds 804B-1, 804B-2, 804C-1, 804C-2, 804D-1, and 804D-2 that are distributed among the other racks 802B, 802C, and 802D of data center 800. The embodiments are not limited to this example. For example, fabric 812 can provide optical and/or electrical signaling.

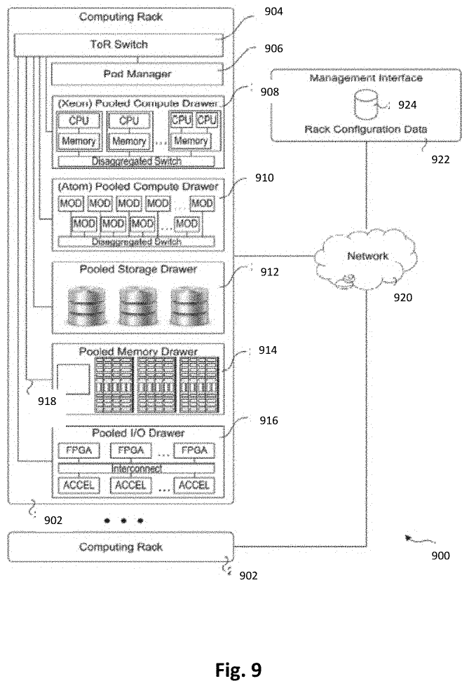

FIG. 9 depicts an environment 900 includes multiple computing racks 902, each including a Top of Rack (ToR) switch 904, a pod manager 906, and a plurality of pooled system drawers. Generally, the pooled system drawers may include pooled compute drawers and pooled storage drawers to, e.g., effect a disaggregated computing system. Optionally, the pooled system drawers may also include pooled memory drawers and pooled Input/Output (I/O) drawers. In the illustrated embodiment the pooled system drawers include an INTEL® XEON® pooled computer drawer 908, and INTEL® ATOM™ pooled compute drawer 910, a pooled storage drawer 912, a pooled memory drawer 914, and a pooled I/O drawer 916. Each of the pooled system drawers is connected to ToR switch 904 via a high-speed link 918, such as a 40 Gigabit/second (Gb/s) or 100 Gb/s Ethernet link or an 100+ Gb/s Silicon Photonics (SiPh) optical link. In one embodiment high-speed link 918 comprises an 800 Gb/s SiPh optical link.

Again, the drawers can be designed according to any specifications promulgated by the Open Compute Project (OCP) or other disaggregated computing effort, which strives to modularize main architectural computer components into rack-pluggable components (e.g., a rack pluggable processing component, a rack pluggable memory component, a rack pluggable storage component, a rack pluggable accelerator component, etc.).

Multiple of the computing racks 900 may be interconnected via their ToR switches 904 (e.g., to a pod-level switch or data center switch), as illustrated by connections to a network 920. In some embodiments, groups of computing racks 902 are managed as separate pods via pod manager(s) 906. In one embodiment, a single pod manager is used to manage all of the racks in the pod. Alternatively, distributed pod managers may be used for pod management operations.

RSD environment 900 further includes a management interface 922 that is used to manage various aspects of the RSD environment. This includes managing rack configuration, with corresponding parameters stored as rack configuration data 924.

Any of the systems, data centers or racks discussed above, apart from being integrated in a typical data center, can also be implemented in other environments such as within a bay station, or other micro-data center, e.g., at the edge of a network.

Embodiments herein may be implemented in various types of computing, smart phones, tablets, personal computers, and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, each blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. It is noted that hardware, firmware and/or software elements may be collectively or individually referred to herein as “module,” “logic,” “circuit,” or “circuitry.”

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal. The terms “follow” or “after” can refer to immediately following or following after some other event or events. Other sequences of steps may also be performed according to alternative embodiments. Furthermore, additional steps may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

1. An apparatus,
a module to be inserted into an electronic system, the module comprising:
a) a first heat exchanger at one end of the module and second heat exchanger at another end of the module; and,
b) a first vapor chamber that runs along respective integrated heat spreaders of semiconductor chips disposed on a first side of the module and a second vapor chamber that runs along respective integrated heat spreaders of semiconductor chips disposed on a second side of the module, wherein, the first heat exchanger is in thermal contact with at least one of the first and second vapor chambers, and, the second heat exchanger is in thermal contact with at least one of the first and second vapor chambers.

2. The apparatus of claim 1 wherein the first and second vapor chambers are closed vapor chambers.

3. The apparatus of claim 2 wherein a thermal interface material is disposed between the first heat exchanger at the least one of the first and second vapor chambers that the first heat exchanger is in thermal contact with.

4. The apparatus of claim 1 wherein the first and second vapor chambers are open vapor chambers.

5. The apparatus of claim 4 further comprising at least one respective fluidic channel between the at least one of the first and second vapor chambers that the first heat exchanger is in thermal contact with.

6. The apparatus of claim 1 further comprising a thermal interface material between the first vapor chamber and the respective integrated heat spreaders of the semiconductor chips disposed on the first side of the module.

7. The apparatus of claim 1 wherein the first heat exchanger is mechanically integrated with the first vapor chamber such that no thermal interface material exists between the first heat exchanger and the first vapor chamber.

8. The apparatus of claim 1 wherein an inner face of the first heat exchanger is in thermal contact with a respective outer face of the at least one of the first and second vapor chambers that the first exchanger is in thermal contact with.

9. The apparatus of claim 1 where the first and second heat exchangers are to be in thermal contact with first and second cold plates of the electronic system.

10. The apparatus of claim 1 where the module is a memory module.

11. The apparatus of claim 1 wherein at least one of the first and second vapor chambers collapses and expands as a function of heat received from its respective ones of the semiconductor chips.

12. A computing system, comprising:
a plurality of processing cores;
a memory controller coupled to the processing cores;
a liquid cooling system;
a main memory coupled to the memory controller, the main memory comprising a memory module, the module comprising:
a) a first heat exchanger at one end of the memory module coupled to a first cold plate of the liquid cooling system and second heat exchanger at another end of the memory module, coupled to a second cold plate of the liquid cooling system; and,
b) a first vapor chamber that runs along respective integrated heat spreaders of semiconductor chips disposed on a first side of the module and a second vapor chamber that runs along respective integrated heat spreaders of semiconductor chips disposed on a second side of the module, wherein, the first heat exchanger is in thermal contact with at least one of the first and second vapor chambers, and, the second heat exchanger is in thermal contact with at least one of the first and second vapor chambers.

13. The computing system of claim 12 wherein the first and second vapor chambers are closed vapor chambers.

14. The computing system of claim 12 wherein the first and second vapor chambers are open vapor chambers.

15. The computing system of claim 12 further comprising a thermal interface material between the first vapor chamber and the respective integrated heat spreaders of the semiconductor chips disposed on the first side of the module.

16. The computing system of claim 12 wherein the first heat exchanger is mechanically integrated with the first vapor chamber such that no thermal interface material exists between the first heat exchanger and the first vapor chamber.

17. The computing system of claim 12 wherein an inner face of the first heat exchanger is in thermal contact with a respective outer face of the at least one of the first and second vapor chambers that the first exchanger is in thermal contact with.

18. The computing system of claim 12 where the first and second heat exchangers are to be in thermal contact with first and second cold plates of the electronic system.

19. The computing system of claim 11 where the module is a memory module.

20. A method, comprising:
operating a module having first semiconductor chips disposed on a first side of the module and having second semiconductor chips disposed on a second side of the module;
vaporizing first liquid in a first vapor chamber that is in thermal contact with the first semiconductor chips and vaporizing second liquid in a second vapor chamber that is in thermal contact with the second semiconductor chips;
condensing the vaporized first and second liquids in first and second heat exchangers that are disposed at ends of the module.
